(19) United States
(12) Patent Application Publication
(10) Pub. No.: US 2025/0275659 A1
(43) Pub. Date: Sep. 4, 2025

(54) SUCTION UNIT WITH COOLING USING FRESH AIR

(71) Applicant: BSH Hausgeräte GmbH, München (DE)

(72) Inventors: Sebastian BACK, Burglauer (DE); Stefan BOCKELT, Rödelmaier (DE); Christian FROMM, Bad Neustadt (DE); Christian SCHELER, Rödelmaier (DE); Marcel STENGEL, Sulzfeld (DE); Christian STOBERT, Hohenroth (DE); Frank SCHNITZER, Bad Neustadt (DE); Silvio HAMM, Sülzfeld (DE)

(21) Appl. No.: 19/069,440

(22) Filed: Mar. 4, 2025

(30) Foreign Application Priority Data
Mar. 4, 2024 (DE) 10 2024 202 005.2

(51) Int. Cl. A47L 9/28; A47L 9/32; H05K 7/20

(52) U.S. Cl. CPC A47L 9/2889; A47L 9/2884; A47L 9/322; H05K 7/20145

(57) ABSTRACT

A suction unit for a handheld vacuum appliance contains a blower configured to generate a main suction air stream from the suction mouth via a separating unit to the blower of the suction unit. The suction unit has a handle with a cavity which is formed by a housing wall and in which an electronics component is arranged. The cavity has an inlet opening in the housing wall. The suction unit has a bypass channel which has an inlet facing toward the cavity and an outlet facing toward the blower. The blower is configured to generate a bypass air stream from the inlet opening, through the cavity and through the bypass channel to the blower. The cavity is covered by a shielding element which is configured to shield the cavity against moisture from the main suction air stream and/or from exhaust air from the blower.

### CROSS-REFERENCE TO RELATED APPLICATION

This application claims the priority, under 35 U.S.C. § 119, of German Patent Application DE 10 2024 202 005.2, filed Mar. 4, 2024; the prior application is herewith incorporated by reference in its entirety.

### FIELD AND BACKGROUND OF THE INVENTION

The invention relates to a suction unit for a vacuum appliance, in particular for a wireless and/or handheld vacuum mop.

A vacuum appliance, in particular a handheld vacuum cleaner, typically contains a suction unit that a user can carry and control by hand. The suction unit has a blower that is operated using electrical energy from an electrical energy store of the suction unit. The blower is configured to generate a suction air stream in order to suction contaminants through a suction mouth of the suction unit into a collecting container of the suction unit. The suction mouth of the suction unit is typically configured as a coupling by means of which in each case one accessory part from a set of different accessory parts can be connected to the suction unit. An example of an accessory part is a wet cleaning nozzle, which makes it possible to simultaneously mop and vacuum a surface that is to be cleaned.

If the vacuum appliance is used as a combined vacuum mop, the suction air stream may contain moisture, and the suction air stream can therefore no longer be directly used to cool the electronics of the suction unit.

Published, non-prosecuted German patent application DE 17 03 970 A describes a vacuum cleaner having an inlet hole for ambient air. Published, European patent application EP 3 763 265 A1 describes a portable vacuum apparatus.

Published, non-prosecuted German patent application DE 10 2012 207 348 A1 describes a vacuum cleaner having a secondary air channel. Published, non-prosecuted German patent application DE 10 2014 200 663 A1 (corresponding to U.S. Pat. No. 9,370,285) describes a battery-powered handheld vacuum cleaner. German utility model DE 20 2012 101 781 U1 describes a vacuum apparatus for hard surfaces.

### SUMMARY OF THE INVENTION

The present document is concerned with the technical problem of achieving efficient and reliable cooling of the electronics of the suction unit of a vacuum appliance, in particular of a vacuum appliance that can be used as a vacuum mop, such that the suction air stream may contain moisture.

The problem is solved by the subject matter of the independent patent claim. Advantageous embodiments are in particular defined in the dependent patent claims, described in the following description or shown in the appended drawing.

With the foregoing and other objects in view there is provided, in accordance with the invention, a suction unit for a handheld vacuum appliance. The suction unit contains a suction mouth, a separating unit, and a blower configured to generate a main suction air stream from the suction mouth via the separating unit to the blower of the suction unit. The suction unit further has a handle with a housing wall defining a cavity, and in the handle an electronic component is disposed. The cavity has at least one inlet opening formed in the housing wall. A bypass channel has an inlet facing toward the cavity and an outlet facing toward the blower. The blower is configured to generate a bypass air stream from the at least one inlet opening, through the cavity and through the bypass channel to the blower. The cavity is covered, on a side facing toward the inlet of the bypass channel, by a shielding element configured to shield the cavity against moisture from the main suction air stream and/or from exhaust air from the blower. The shielding element has a sealed opening and in the sealed opening the inlet of the bypass channel is disposed.

In one aspect, a suction unit for a handheld vacuum appliance is described. The suction unit contains a blower which is configured to generate a main suction air stream from the suction mouth (or the suction tube) of the suction unit via the separating unit of the suction unit to the blower of the suction unit. If appropriate, a wet cleaning nozzle may be connected to the suction mouth or to the suction tube, such that the main suction air stream may include moisture (in addition to dust). The blower may be arranged above the separating unit as viewed along a vertical axis of the suction unit. The separating unit typically contains a collecting container for receiving suctioned dirt.

The suction unit furthermore contains a handle having a cavity which is formed by a housing wall and in which an electronics component is arranged (wherein the electronics component may be designed to control the blower). The cavity has one or more inlet openings in the housing wall. The handle may be designed to be gripped by a user using one hand for the purposes of holding the suction unit. The handle may be arranged behind the blower and the separating unit as viewed along a longitudinal axis of the suction unit (which extends perpendicularly to the vertical axis). The handle may (like the handle of a jug) extend along the vertical axis from the top side of the suction unit (at which the blower is arranged) to the bottom side of the suction unit (at which the energy store of the suction unit and/or the bottom side of the separating unit is arranged). The cavity having the electronics component may be arranged at the bottom side of the suction unit (directly above the holder for the energy store as viewed along the vertical axis).

The handle may be part of a housing of the suction unit. The blower may also be arranged in the housing. The housing may furthermore have a connection region which faces toward the side wall of the separating unit (with the collecting container) and which extends from the bottom side to the top side of the suction unit. The connection region may thus extend substantially along the vertical axis. The handle may, together with the connection region, form a ring. The connection region may have a coupling at which the separating unit can be fastened to the housing of the suction unit.

The suction unit furthermore contains a bypass channel which has an inlet facing toward the cavity and an outlet facing toward the blower. The bypass channel may extend within the connection region of the housing of the suction unit. Here, the bypass channel may extend along the vertical axis from the bottom side of the suction unit (at which the cavity is arranged) to the top side of the suction unit (at which the blower is arranged). The bypass channel may contain a bypass hose. In particular, the bypass channel may be formed in an efficient manner as a bypass hose.

The blower is configured to generate a bypass air stream from the one or more inlet openings, through the cavity and through the bypass channel to the blower. The blower is thus made capable of generating a bypass air stream in addition to and separately from the main suction air stream in order to achieve efficient and reliable cooling of the electronics component. Here, the bypass air stream has fresh ambient air, such that particularly reliable cooling can be achieved. Furthermore, the bypass air stream does not contain moisture from the main suction air stream, thus making careful cooling of the electronics component possible.

The electronics component may have a first edge facing toward the inlet of the bypass channel. The one or more inlet openings are preferably arranged at the second edge of the electronics component, the second edge facing away from the inlet of the bypass channel, wherein the first and the second edge of the electronics component are arranged opposite one another. Particularly reliable cooling of the electronics component can thus be achieved.

The electronics component has (in relation to the vertical axis) a first side (in particular a bottom side) and a second side (in particular a top side). The one or more inlet openings may face toward the first side (in particular the bottom side) of the electronics component, and the inlet of the bypass channel may face toward the second side (in particular the top side) of the electronics component. Particularly reliable cooling of the electronics component by means of the bypass stream can thus be achieved.

The inlet of the bypass channel may constitute a constriction in relation to the cavity, such that the bypass air stream within the cavity is accelerated and/or compressed toward the inlet of the bypass channel. The cooling effect can thus be further improved.

The cavity is preferably covered, on the side facing toward the inlet of the bypass channel, by a shielding element which is configured to shield the cavity against moisture from the blower and/or from the main suction air stream and/or from exhaust air from the blower. Here, the shielding element preferably has a sealed opening (with an annular seal) in which the inlet of the bypass channel is arranged. Through the provision of a wall-like shielding element, the electronics component can be particularly reliably and efficiently protected against moisture.

The electronics component may have a circuit board (on which one or more electronic devices are arranged). The circuit board and the shielding element may be arranged at an acute angle with respect to one another, in particular at an angle of 75° or less. It is thus possible for the bypass air stream to be focused in order to achieve improved cooling of the electronics component.

As already stated, the blower may be arranged above the separating unit as viewed along the vertical axis of the suction unit. Furthermore, the cavity may be arranged below the blower as viewed along the vertical axis. The bypass channel may extend (within the connection region of the housing of the suction unit) along the vertical axis from the cavity to the inlet of the blower.

At least one portion of the bypass channel may extend above the inlet of the blower as viewed along the vertical axis. The portion of the bypass channel may be configured such that a flow of moisture through the portion of the bypass channel from the inlet of the blower to the inlet of the bypass channel is impeded. The electronics component can thus be particularly reliably protected against moisture.

The suction unit may be configured such that the exhaust air from the blower is conducted (within the connection region of the housing) along the vertical axis, along the bypass channel and along the side wall of the separating unit to an outlet opening that is arranged below the blower as viewed along the vertical axis, in particular on the bottom side of the suction unit. Here, by means of the shielding element, it can be achieved at no moisture from the exhaust air enters the cavity having the electronics component. The convenience of the suction unit can be increased by virtue of the exhaust air flowing out at the bottom side of the suction unit.

The suction unit may thus be designed such that the exhaust air from the blower and the bypass air stream run adjacent to one another within the connection region of the housing of the suction unit. The exhaust air and the bypass air stream may in this case have opposite flow directions. In particular, the exhaust air may flow along the vertical axis from the top side toward the bottom side of the suction unit. On the other hand, the bypass air stream may flow along the vertical axis from the bottom side toward the top side of the suction unit. The bypass air stream is conducted within the bypass channel and is therefore separate from the exhaust air (which, for example, flows freely to the bottom side of the suction unit within the connection region of the housing). Particularly efficient and reliable air guidance within the housing of the suction unit can thus be achieved.

The blower may be embedded in a blower capsule, wherein the blower capsule has a connection element. The outlet of the bypass channel may be mechanically connected to the connection element, in particular fitted onto the connection element. Efficient and reliable fixing of the bypass channel can thus be achieved.

As already stated, the suction unit may have an electrical energy store which is arranged at the one or more inlet openings such that the bypass air stream flows past at least a subregion of the energy store. Particularly efficient cooling of the electrical energy store of the suction unit can thus be achieved.

The suction mouth of the suction unit has a main cross-sectional area, and the bypass channel has a bypass cross-sectional area. The main cross-sectional area is preferably larger than the bypass cross-sectional area by a factor of 10 or more, in particular by a factor of 100 or more. As a result, the bypass channel does not result in any significant impairment of the suction power of the suction unit.

The housing wall that forms the cavity may have, on the inner side facing toward the cavity, one or more guide fins and/or guide protuberances that are each designed to conduct the bypass air stream through the cavity past the electronics component. Alternatively or in addition, the circuit board may comprise one or more drilled holes and/or cutouts through which a proportion of the bypass air stream flows when the blower is in operation. The cooling of the electronics component can thus be further improved.

According to a further aspect, a suction unit for a handheld vacuum appliance is described, wherein the suction unit comprises a blower which is configured to generate a main suction air stream from the suction mouth of the suction unit via a separating unit of the suction unit to the blower of the suction unit. It should be noted that the features described in this document are also applicable individually or in combination to this suction unit.

The suction unit contains a housing having a housing wall which forms a cavity in which an electronics component is arranged, the electronics component being designed to control the blower, for example. The cavity has one or more inlet openings in the housing wall.

The suction unit furthermore contains a bypass channel which has an inlet facing toward the cavity and an outlet facing toward the blower. The blower is configured to generate a bypass air stream from the one or more inlet openings, through the cavity and through the bypass channel to the blower.

The inlet of the bypass channel preferably constitutes a constriction in relation to the cavity, such that the bypass air stream within the cavity is accelerated and/or compressed toward the inlet of the bypass channel. Particularly reliable and efficient cooling of the electronics component of the suction unit can thus be achieved.

According to a further aspect, a vacuum appliance, in particular a handheld vacuum cleaner (with mop function), is described, which comprises the suction unit described in this document.

It should be noted that all aspects of the suction unit described in this document and of the vacuum appliance described in this document may be combined with one another in a variety of ways. In particular, the features of the patent claims may be combined with one another in a variety of ways.

Other features which are considered as characteristic for the invention are set forth in the appended claims.

Although the invention is illustrated and described herein as embodied in a suction unit with cooling using fresh air, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a diagrammatic, perspective view of an exemplary vacuum appliance having a suction unit, a suction tube and a nozzle;

FIG. 2A is a section view of a suction unit having a bypass channel;

FIG. 2B is a section view of an electronics component of the suction unit;

FIG. 2C is a sectional view of a main suction air stream and a bypass air stream of the suction unit;

FIGS. 3A and 3B are different perspective views of the blower capsule; and

FIG. 4 is a perspective view of an exemplary shielding element for shielding the electronics component.

### DETAILED DESCRIPTION OF THE INVENTION

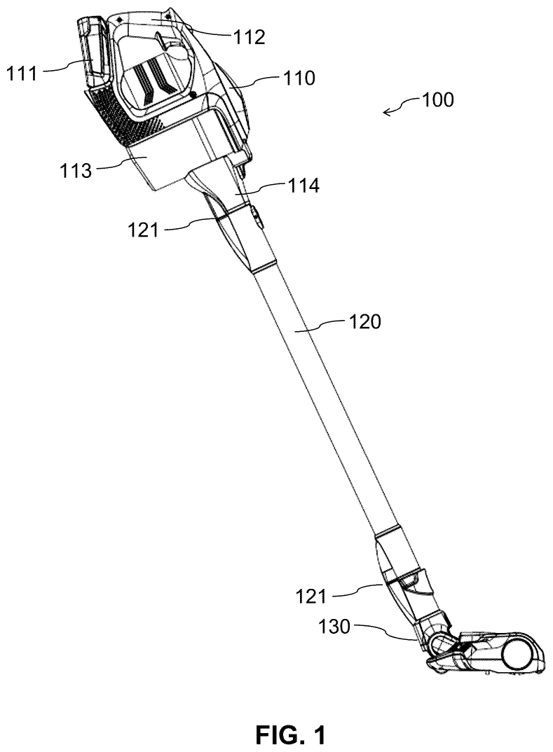

As discussed in the introduction, the present document is concerned with achieving efficient and reliable cooling of the electronics of a suction unit of a vacuum appliance that can also be used as a vacuum mop. In this context, FIG. 1 shows an exemplary (handheld) vacuum cleaner 100 (as an example of a vacuum appliance) containing a suction unit 110 that has an electrical energy store 111. The suction unit 110 has a handle 112 that a user can grip using one hand in order to hold the suction unit 110. The blower of the suction unit 110 generates a suction air stream through the suction mouth 114 of the suction unit 110 via a separating unit 113 of the suction unit 110 to the blower. The suction unit 110 may be configured to be used on its own as a vacuum appliance.

An accessory part 120, 130 can be connected by means of a coupling 121 to the suction unit 110. In the example illustrated, the suction unit 110 is connected by means of a coupling 121 to a suction tube 120, which in turn is connected by means of a coupling 121 to a floor nozzle 130. The floor nozzle 130 may be designed as a wet cleaning nozzle.

The suction air stream generated by the blower of the suction unit 110 may be used to cool an electronics component and/or the energy store 111 of the suction unit 110. If a wet cleaning nozzle is used, the suction air stream may contain moisture, which can damage the electronics component and/or the energy store 111.

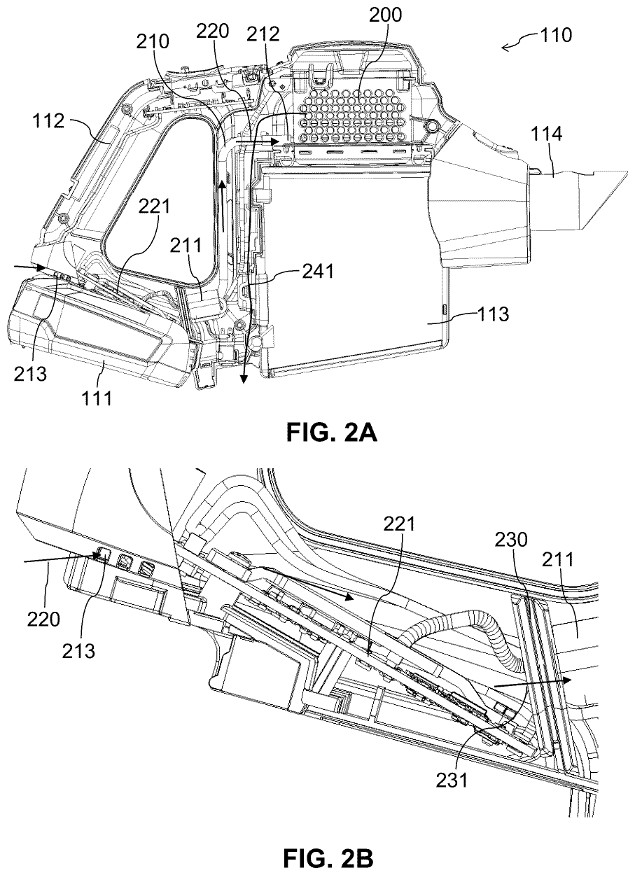

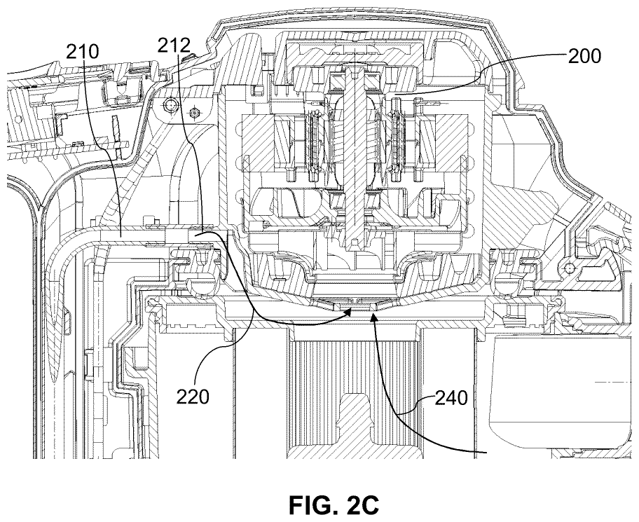

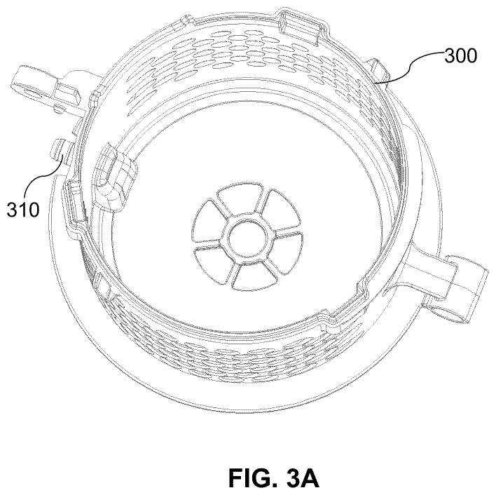

FIGS. 2A to 2C show different views of a suction unit 110 which has a bypass channel 210 fluidically coupled to the blower 200, such that the blower 200 can generate a bypass air stream 220 in the bypass channel 210. The bypass channel 210 may be formed by a hose. The bypass channel 210 extends from the blower 200 through the housing of the suction unit 110 in the direction of the electronics component 221 and/or the energy store 111 of the suction unit 110, such that the bypass air stream 220 flows past the electronics component 221 and/or past the energy store 111.

As can be seen in particular from FIG. 2B, the electronics component 221 may be shielded from the blower 200 by means of a shielding element 230, in particular in order to prevent moisture from passing from the blower 200 and/or from the exhaust air 241 from the blower 200 to the electronics component 221. The bypass channel 210 may be arranged on that side of the shielding element 230 which faces toward the blower 200, and the electronics component 221 may be arranged on that side of the shielding element 230 which faces away from the blower 200. The shielding element 230 may have a sealed opening 231 in which the inlet 211 of the bypass channel 210 is arranged. It can thus be achieved that the bypass air stream 220 passes via the electronics component 221, through the opening 231 of the shielding unit 230 and into the inlet 211 of the bypass channel 210.

The electronics component 221 is enclosed by the housing wall of the handle 112 of the suction unit 110. The housing wall has one or more entry openings 213 via which the bypass air stream 220 enters the housing from the outside and arrives at the electronics component 221. The one or more entry openings 213 are arranged at that side of the electronics component 221 which faces away from the inlet 211 of the bypass channel 210, such that the bypass air stream 220 flows from the one or more entry openings 213 via the electronics component 221 to the inlet 211 of the bypass channel 210, and in so doing cools the electronics component 221.

As can be seen from FIG. 2C, the blower 200 thus generates not only the main suction air stream 240 (which flows through the separating unit 113 of the suction unit 110, as illustrated in FIG. 2A) but also the bypass air stream 220 through the bypass channel 210.

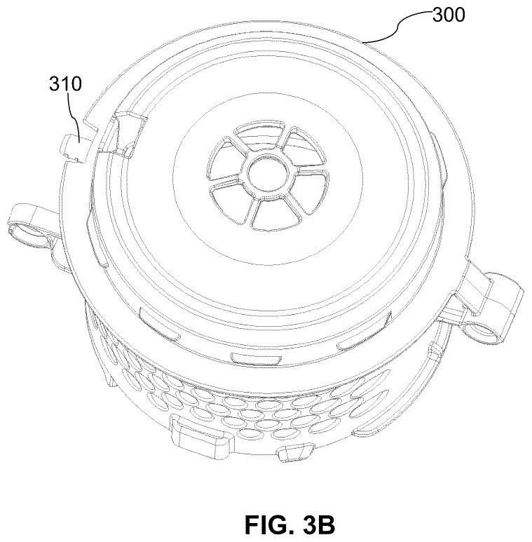

FIGS. 3A and 3B show different views of the blower capsule 300 which encloses the blower 200. The blower capsule 300 may have a connection element 310 for the connection of the outlet 212 of the bypass channel 210. The outlet 212 of the bypass channel 210 can for example be pushed onto the connection element 310 in order to fix the outlet 212 of the bypass channel 210 to the blower capsule 300. The bypass air stream 220 can thus be generated in a particularly stable manner.

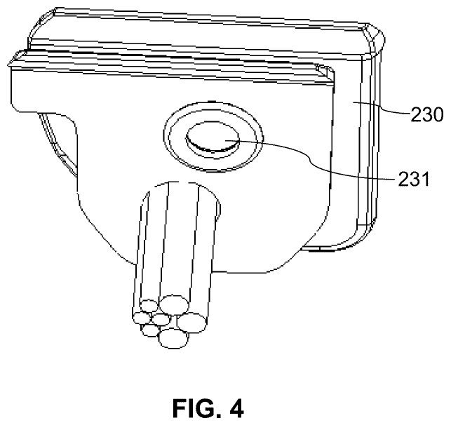

FIG. 4 shows an exemplary shielding element 230 having the sealed opening 231 for the inlet 211 of the bypass channel 210.

It is thus possible for the electronics 221 in the handle 112 of the suction unit 110 to be cooled by means of a supply of fresh air that is drawn in through a secondary air channel (that is to say through the bypass channel 210). The collecting container (as part of the separating unit 113), the blower 200, the handle 112, the control electronics 221 for the blower 200 and/or a holder for the electrical energy store 111 may be integrated in the suction unit 110 (that is to say in the handheld part of the vacuum appliance 100). The air stream 240 that is supplied from the tube (that is to say the suction mouth 114) is conducted through the collecting container and the filter of the separating unit 113 to the blower 200. The exhaust air 241 from the blower 200 may furthermore be conducted onward into the handle 112 and/or through the connection region of the housing of the suction unit (to the bottom side of the suction unit 110; as illustrated by way of example in FIG. 2A).

The cooling of the electronics 221 is effected by means of a bypass channel 220 through which fresh air from the outside is drawn into the handle 112. A bypass channel 210 (in particular a bypass hose) is positioned close to the inlet of the blower 200. During operation, the negative pressure that is generated by the blower 200 at the inlet of the blower draws in an air stream 220 from the bypass channel 210. The air that is drawn into the bypass channel 210 at the channel inlet side 211 originates from a (largely) closed-off cavity of the handle 112, in which the electronics 221 are arranged. Fresh air flows in through one or more entry openings 213 on the housing wall close to the holder for the energy store 111 and flows around the electronics 221. That region of the handle 112 in which the electronics 221 are positioned may be separated from the rest of the interior of the handle 112 by partitions (that is to say by a shielding element 230) such that the exhaust air 241 from the blower 200 which is conducted by the blower 200 into the handle 112 and/or into the connection region of the housing of the suction unit 110 does not reach the electronics 221, and therefore cannot mix with the fresh air, before exiting the suction unit 110 via exit openings in the housing of the suction unit 110 (on the bottom side of the suction unit 110).

By virtue of the one or more entry openings 213 for the fresh air being arranged in the region of the holder for the energy store 111, simultaneous cooling of the electronics 221 and of the energy store 111 is achieved. Here, air which is at ambient temperature and which is therefore significantly cooler than the exhaust air 241 from the blower 200 flows both around the housing of the energy store 111 and around the electronics 221. In the cavity of the handle 112 having the integrated electronics 221, the fresh air flowing in to the bypass channel 210 is conducted around the electronics 221 and, in the process, flows over large parts of the board (that is to say the circuit board) of the electronics 221, or over large parts of the electronics 221, rather than being directed only locally onto a small portion. The one or more entry openings 213 for the fresh air are preferably situated laterally in the housing below the electronics board, whereas the inlet side 211 of the bypass channel 210 is situated above the electronics board. The air that is drawn in to the bypass channel 210 thus flows around the entire board before being focused on the inlet 211 of the bypass channel 210. The electronics components arranged in this portion of the electronics 221 are thus cooled particularly effectively, because the flow velocity and the flow density in the vicinity of the inlet 211 of the bypass channel 210 are increased.

The partition 230 (that is to say the shielding element) situated in the hand 112 at the inlet 211 of the bypass channel 210 is preferably arranged at a certain angle (obliquely) with respect to the electronics board 221, such that the board 221 and the partition 230 enclose an acute angle. This arrangement reduces the volume of the cavity in the unused region and assists the supply of air into the bypass channel 210 and the concentration of the air in the region close to the inlet 211 of the bypass channel 210.

The flow rate of the fresh air that is drawn in for the purposes of cooling the electronics 221 can be set by means of the internal diameter of the bypass channel 210. The ratio of the internal diameter of the bypass channel 210 to the internal diameter of the suction tube 114 (that is to say of the suction mouth) substantially defines the flow rate of the fresh air. The internal diameter of the bypass channel 210 may for example be 3 mm, and the internal diameter of the suction tube 114 may be 30 mm, such that the area of the cross section of the bypass channel 210 is for example one hundredth of the area of the cross section of the suction tube 114.

The air stream 220 from the bypass channel 210 exits the bypass channel 210 at a coupling means 310 to the side of the blower 200. The air 220 is conducted from the coupling means to the inlet of the blower 200, where said air mixes with the air 240 drawn in from the collecting container and is drawn into the blower 200. Owing to the elevated position of the outlet 212 of the bypass channel 210 relative to the inlet of the blower 200 and the associated increased distance of the bypass channel 210 from the moisture-carrying air stream 240 from the collecting box, no additional measures such as filters are necessary to protect the bypass channel 210 against moisture or dust.

A dimensionally stable material (such as PE (polyethylene)) may be used for the bypass channel 210, in particular for the bypass hose. Fixing ribs which additionally stabilize the bypass channel 210 in terms of its shape are preferably incorporated into the housing shells of the handle 112. By means of the fixing ribs, the bypass channel 210 is routed, and its ends 211, 212 are preferably oriented, such that the bypass channel 210 is inclined in the flow direction, and therefore no significant noise generation occurs and no significant flow resistance is generated.

The cross section of the bypass channel 210 may be selected (for example with an external diameter of 5 mm and an internal diameter of 3 mm) so as to ensure an optimum throughput of air for the purposes of cooling the electronics, and at the same time minimize possible vibrations of the bypass channel 210. Furthermore, the wall thickness (for example of 1 mm) of the bypass channel 210 ensures dimensional stability and resistance to distortion with respect to the external heating caused by the heated exhaust air 241 which flows along the outside of the bypass channel 210.

That end 211 of the bypass channel 210 which is oriented toward the electronics 221 is preferably (for the purposes of protecting against moisture) fixed directly in the rubber seal of the electronics shield 230. That end 212 of the bypass channel 210 which leads to the blower 200 may be connected by a flexible elastic coupling means 310 (for example an intermediate piece in the form of a silicone hose, for example) to the blower capsule 300. The bypass channel 210 is thus decoupled from vibrating parts (for example the blower 200) and can absorb vibrations (for example if the appliance is dropped) without any impairment of function.

The cooling air stream 220 is free from drawn-in moisture and may optionally also cool the housing of the energy store 111, because fresh air is drawn in from the outside. Even during operation with a damaged or inadvertently uninstalled filter of the separating unit 113, the electronics 221 cannot come into contact with moisture from the nozzle 130 and/or with suctioned dust, because the electronics are separated from the exhaust air 241 by partitions 230 (that is to say by the shielding element).

Additional fins or protuberances may be integrated in the cavity of the electronics 221 and provide enhanced or improved guidance of air around the electronics 221. The air stream 220 within the cavity can thus be directed to parts of the electronics 221 requiring particularly intense cooling and can be concentrated and accelerated there, or at another location may be conducted more widely over large areas of the electronics board.

The electronics board itself may be provided with drilled holes or cutouts in order to improve the air flow in the region of the electronics and/or in order to conduct air to desired locations that are also situated within the extent of the board but on the other side of the board.

The measures described in this document have the effect that the electronics 211 are cooled by means of fresh ambient air from the outside, which is typically cooler than the exhaust air 241 from the blower 200. It is possible to implement simultaneous cooling of the energy store 111 and of the electronics 221, because the air 220 that is drawn into the housing through the inlet openings 213 also flows over the housing of the energy store 111. Cooling of the entire electronics board can be achieved because the fresh air flows around the entire board and does not merely (locally) draw away warm air.

The bypass air stream 220 for cooling purposes is separate from the main suction air stream, such that moisture and/or dust/dirt cannot enter the bypass air stream 220. The electronics 221 are thus protected against moisture and are not situated in the space that is exposed to dust. The electronics 221 cannot come into contact with dust even if a filter of the separating unit 113 is damaged or uninstalled. The fresh air stream 220 furthermore ensures continuous suctioning of dust away from the electronics 221.

The heated air dissipated from the electronics 221 is supplied via the bypass channel 210 to the blower 200 and is mixed, in the intake region (that is to say at the inlet) of the blower 200, with the air 240 that has been drawn in via the suction channel. From the blower 200 onward, the air stream is therefore warmer than the rest of the ambient air. Since heated air can absorb more moisture than relatively cool air, the moisture contained in the intake air can be more effectively retained in the air stream. The tendency for the moisture to condense within the suction unit 110 is thus reduced, such that an impairment of the suction unit 110, in particular of the blower 200, by moisture can be reduced.

What is described, therefore, is cooling of an electronics board 221 in a handheld vacuum cleaner 100, 110, in which the power supply and the electronics are arranged on/in the handle 112, by means of a bypass channel 210. The one or more cooling air openings 213 are also situated in the handle 112.

Fresh air 220 that is drawn in from the outside flows through the bypass channel 210 in order to cool the electronics 221 and the energy store 111, and therefore an additional structural unit for separating moisture out of the main suction air stream 240, and/or a coating of the electronics 221, can be avoided.

When the blower 200 is in operation, cooling air 220 is drawn in through the openings 213 on the handle 112 and is conducted via the energy store 111 and the electronics 221 in order to cool these. Here, the cooling air 220 can flow freely over the electronics 221. Via a (sealed) constriction 231 arranged downstream (downstream of the electronics 221), the heated air is supplied via a bypass channel 210 (in particular a hose) to the blower 200. The supply takes place upstream of the blower 200 together with the main suction air stream 240. The cooling air is mixed with the dust-laden air (that is to say the main suction air stream 240) in the blower 200 and is then released to the external surroundings via the openings in the handle 112 or in the connection region of the housing of the suction unit 110. The constriction 231 arranged downstream allows cooling air to flow around the entirety of the electronics 221. The bypass channel 210 allows the cooling air to be conducted with low resistance.

What is described, therefore, is a handheld and/or battery-powered vacuum cleaner 100 that has a motor-blower unit 200 for generating suction air 220, 240. The vacuum cleaner 100 contains a main air channel from an entry opening (for example a nozzle 130) via a dust-separating unit 113 to the motor-blower unit 200. The vacuum cleaner 110 furthermore contains a secondary air channel 210 from an entry opening 213 that is arranged on the housing of the vacuum cleaner 100. The vacuum cleaner 100 furthermore has electronics 221, which are to be cooled, in the housing, wherein the electronics 221 are arranged in the secondary air channel.

A constriction 231 may be arranged in the secondary air channel 210, wherein the constriction 231 is arranged downstream of the electronics 221 that are to be cooled. The cooling air 220 can be supplied directly from the constriction 231 to the blower 200. Here, the cooling air may be discharged via a hose. The constriction may be formed by the opening or the inlet 211 of the hose.

The opening 213 of the cavity may be arranged on the handle 112 of the vacuum cleaner 100. The secondary air 220 may be drawn in above the energy store 111 (through the opening 213), and may be such that the secondary air 220 cools the energy store 111.

The entry opening 310 for the cooling air at the end 212 of the channel 210 may be arranged on the blower capsule 300 of the motor-blower unit 200 such that the cooling air 220 is mixed with the main suction air stream 240 directly upstream of a safety guard element of the blower capsule 300.

The present invention is not restricted to the exemplary embodiments shown. In particular, it should be noted that the description and the figures are intended merely to illustrate the principle of the suction unit 110 and/or of the vacuum appliance 100.

The following is a summary list of reference numerals and the corresponding structure used in the above description of the invention:
100 Vacuum appliance (vacuum mop)
110 Suction unit
111 Electrical energy store
112 Handle
113 Separating unit
114 Suction mouth
120 Accessory part (suction tube)
121 Coupling
130 Nozzle (e.g. wet cleaning nozzle)
200 Blower
210 Bypass channel
211 Inlet (bypass channel)
212 Outlet (bypass channel)
213 Entry opening
220 Bypass air stream
221 Electronics component
230 Shielding element
231 Opening
240 Main suction air stream
241 Exhaust air
300 Blower capsule
310 Connection element (for bypass channel)

1. A suction unit for a handheld vacuum appliance, the suction unit comprising:
a suction mouth;
a separating unit;
a blower configured to generate a main suction air stream from said suction mouth via said separating unit to said blower of the suction unit;
a handle having a housing wall defining a cavity, and in said handle an electronic component is disposed, wherein said cavity has at least one inlet opening formed in said housing wall;
a bypass channel having an inlet facing toward said cavity and an outlet facing toward said blower;
said blower configured to generate a bypass air stream from said at least one inlet opening, through said cavity and through said bypass channel to said blower; and
a shielding element, wherein said cavity is covered, on a side facing toward said inlet of said bypass channel, by said shielding element configured to shield said cavity against moisture from the main suction air stream and/or from exhaust air from said blower, and wherein said shielding element has a sealed opening formed therein and in said sealed opening said inlet of said bypass channel is disposed.

2. The suction unit according to claim 1, wherein:
said electronic component has a first edge facing toward said inlet of said bypass channel;
said at least one inlet opening is disposed at a second edge of said electronic component, said second edge facing away from said inlet of said bypass channel; and
said first edge and said second edge of said electronic component are disposed opposite one another.

3. The suction unit according to claim 1, wherein:
said electronic component has a first side and a second side situated opposite said first side;
said at least one inlet opening faces toward said first side of said electronic component; and
said inlet of said bypass channel faces toward said second side of said electronic component.

4. The suction unit according to claim 1, wherein said inlet of said bypass channel constitutes a constriction in relation to said cavity, such that the bypass air stream within said cavity is accelerated and/or compressed toward said inlet of said bypass channel.

5. The suction unit according to claim 1, wherein:
said electronic component has a circuit board; and
said circuit board and said shielding element are disposed at an acute angle with respect to one another.

6. The suction unit according to claim 1, wherein:
said blower is disposed above said separating unit as viewed along a vertical axis of the suction unit;
said cavity is disposed below said blower as viewed along the vertical axis; and
said bypass channel extends along the vertical axis from said cavity to an inlet of said blower.

7. The suction unit according to claim 6, wherein at least one portion of said bypass channel extends above said inlet of said blower as viewed along the vertical axis, such that a flow of moisture through said portion of said bypass channel from said inlet of said blower to said inlet of said bypass channel is impeded.

8. The suction unit according to claim 6, wherein the suction unit is configured such that the exhaust air from said blower is conducted along the vertical axis, along said bypass channel and along a side wall of said separating unit to an outlet opening that is disposed below said blower as viewed along the vertical axis.

9. The suction unit according to claim 1, wherein said bypass channel has a bypass hose.

10. The suction unit according to claim 1, further comprising a blower capsule, said blower is embedded in said blower capsule, said blower capsule has a connection element, and said outlet of said bypass channel is mechanically connected to said connection element.

11. The suction unit according to claim 1, wherein the suction unit has an electrical energy store which is disposed adjacent to said at least one inlet opening such that the bypass air stream flows past at least a subregion of said electrical energy store.

12. The suction unit according to claim 1, wherein:
said suction mouth has a main cross-sectional area;
said bypass channel has a bypass cross-sectional area; and
said main cross-sectional area is larger than said bypass cross-sectional area by a factor of at least 10.

13. The suction unit according to claim 1, wherein said housing wall that forms said cavity has, on an inner side facing toward said cavity, at least one guide fin and/or guide protuberance that are each configured to conduct the bypass air stream through said cavity past said electronic component.

14. The suction unit according to claim 1, wherein:
said electronic component has a circuit board; and
said circuit board has at least one drilled hole and/or cutout formed therein and through which a proportion of the bypass air stream flows when said blower is in operation.

15. The suction unit according to claim 5, wherein the acute angle is an angle of 75° or less.

16. The suction unit according to claim 10, wherein said outlet of said bypass channel is mechanically fitted on said connection element.

17. The suction unit according to claim 12, wherein said main cross-sectional area is larger than said bypass cross-sectional area by a factor of at least 100.
